(19) United States
(12) Patent Application Publication
(10) Pub. No.: US 2007/0059939 A1
(43) Pub. Date: Mar. 15, 2007

(54) Method of producing a conductive layer on a substrate

(75) Inventor: Jeffrey A. Chapman, Burgess Hill (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 10/576,316

(22) PCT Filed: Oct. 15, 2004
(86) PCT No.: PCT/IB04/52105

§ 371 Date: Apr. 18, 2006

(30) Foreign Application Priority Data
Oct. 22, 2003 (GB) 0324561.0

(51) Int. Cl. H01L 21/302

(52) U.S. Cl. 438/719

(57) ABSTRACT

A method of producing a conductive layer (5) on a substrate (1) comprises depositing an insulator such as a photodefinable insulator (2) on the substrate (1), defining a groove (3) for the conductive layer (5) in the insulator material, filling the groove (3) with a precursor material and curing the material to provide the conductive layer.

This application relates to a method of producing a conductive layer on a substrate and a device made using the method, particularly but not exclusively to using a photodefinable damascene process for producing conductive layers on substrates, for example for use as address lines in Active Matrix Liquid Crystal Displays (AMLCDs).

As LCD matrix arrays get larger and more complex, the requirement to obtain low resistance address lines becomes progressively more important. One way to reduce line resistance is to produce thicker address lines using, for example, a damascene process. WO-A-02/47447 discloses a method of forming a printed circuit board using an ink jet printhead, by printing a three dimensional groove using a curable, non-conductive deposition liquid and depositing a liquid in the groove that dries to form a conductive track. In this case, the groove is defined by the walls printed on either side of it. However, the ink jet method is not particularly suitable for obtaining coverage over large areas, as required for an LCD matrix array. Furthermore, the ink jet method will suffer from the disadvantage of having a periodicity due to the droplets needing to overlap along the edge of the groove.

The present invention aims to address the above problems. The invention also aims to provide alternative ways of defining grooves for receiving a conductive material.

According to a first aspect of the invention, there is provided a method of producing a conductive layer on a substrate, comprising the steps of defining a groove for the conductive layer using a photodefinable insulator material and filling the groove with a material capable of forming the conductive layer.

The groove defined in the photodefinable insulator material can have steep walls and so may provide for good confinement of the conductive material. It may also tend to result in a groove with rounded top edges, which may assist in preventing fractures developing in subsequent layers which are deposited over the groove and which descend into the groove to connect to the conductive material within it.

The method may advantageously be used for providing conductive layers on substrates to be used in active matrix liquid crystal displays.

According to the invention, there is also provided a device comprising a substrate overlaid with a photodefinable insulator material, the material having a groove for a conductive layer defined therein. The device may further include a conductive layer in the groove.

The device may be an active matrix liquid crystal display.

According to a second aspect of the invention, there is provided a method of producing a conductive layer on a substrate, comprising the steps of defining a groove for the conductive layer and blading a material capable of forming the conductive layer into the groove.

Blading techniques commonly used in the filling of cliches for offset lithography printing processes may advantageously be adapted for use in producing a conductive layer on a substrate according to the second aspect of invention. The method may provide for a very quick way of filling the groove with an even amount of material.

The groove may be defined by printing an insulating layer onto the substrate so as to define the groove or by depositing a material onto the substrate and subsequently defining the groove in the deposited material, which may be a photodefinable insulator.

According to a third aspect of the invention, there is provided a method of producing a conductive layer on a substrate for an active matrix liquid crystal display, the method comprising the steps of printing an insulating material onto the substrate such that the printed material defines a groove for the conductive layer and filling the groove with a material capable of forming the conductive layer.

Printing techniques may be advantageously used in the production of substrates for active matrix liquid crystal displays.

For a better understanding of the invention, embodiments thereof will now be described, purely by way of example, with reference to the accompanying drawings, in which:

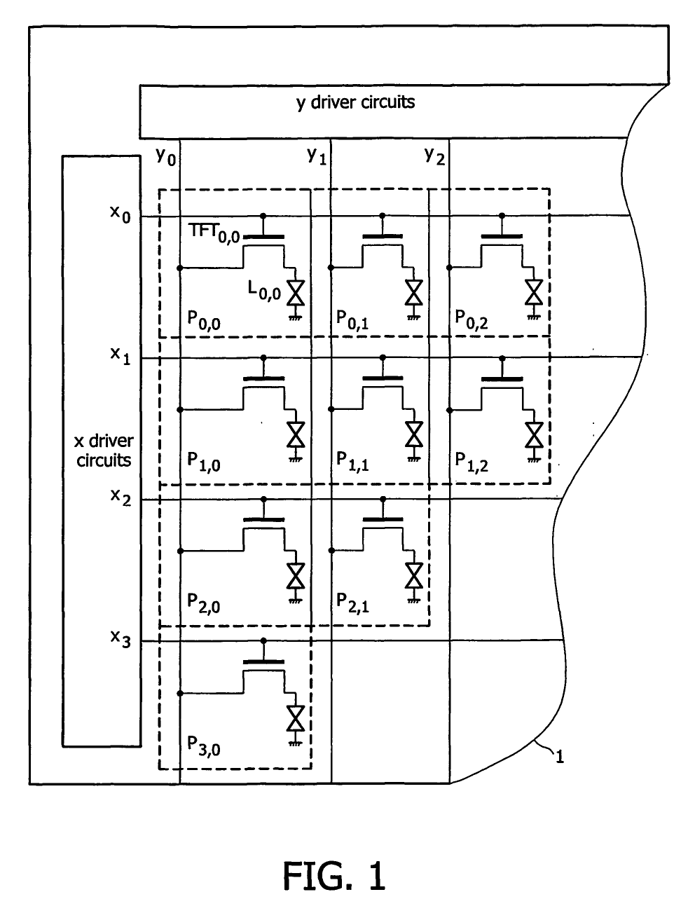

FIG. 1 is a schematic illustration of an AMLCD incorporating thin film transistors (TFTs);

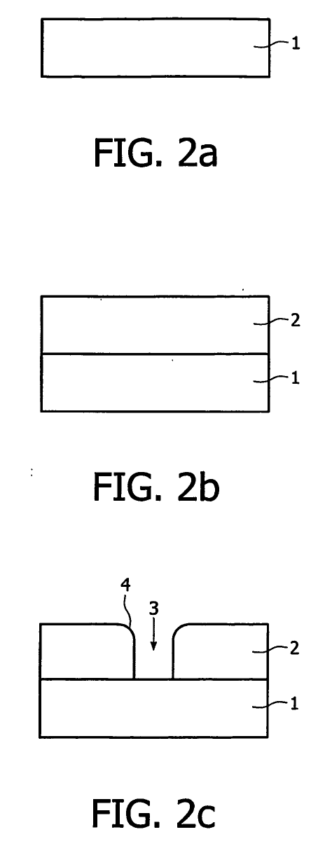

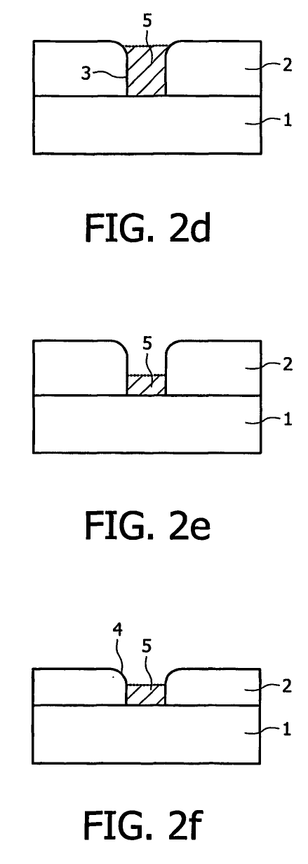

FIGS. 2a to 2f illustrate the steps in the production of a conductive layer, for example a row or column address line in FIG. 1, according to the invention;

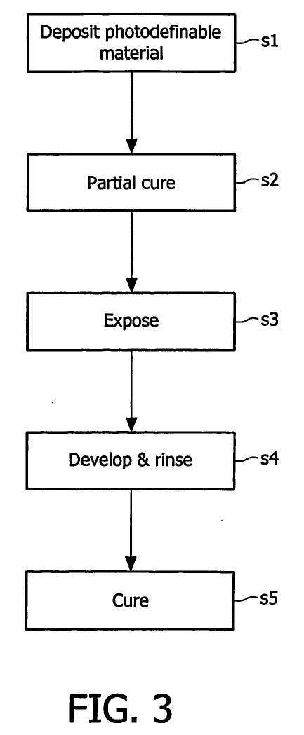

FIG. 3 is a flow diagram explaining the processes used for the production of the stages in FIGS. 2a to 2c of FIG. 2;

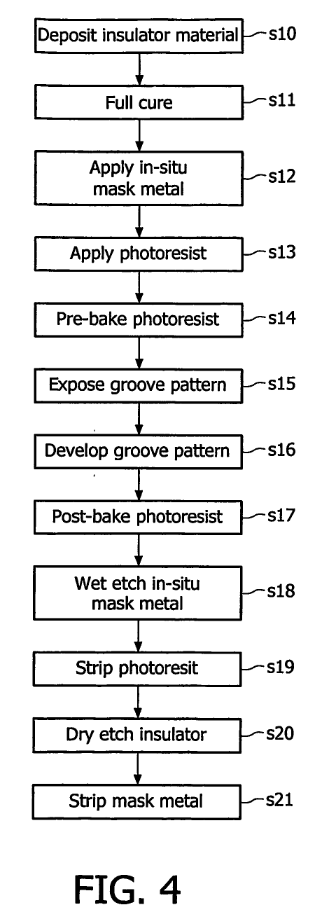

FIG. 4 is a flow diagram illustrating an alternative process for producing a groove on a substrate according to the invention;

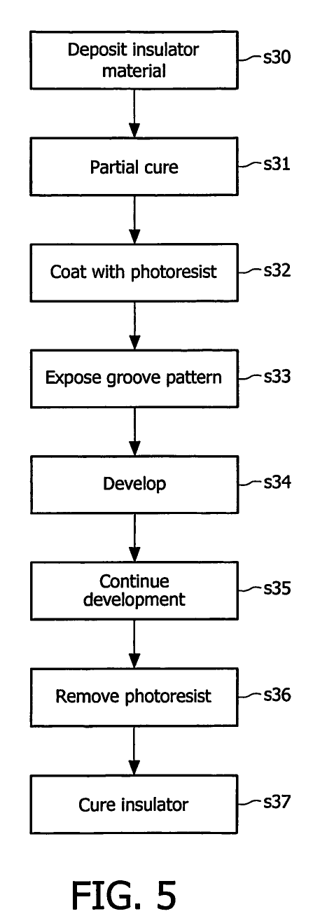

FIG. 5 is a flow diagram illustrating a further alternative process for producing a groove on a substrate according to the invention;

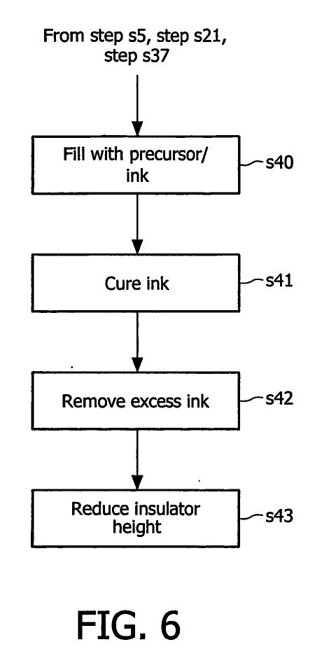

FIG. 6 is a flow diagram illustrating the steps required to fill the groove produced by any method according to the invention, so as to produce a conductive layer in the groove; and

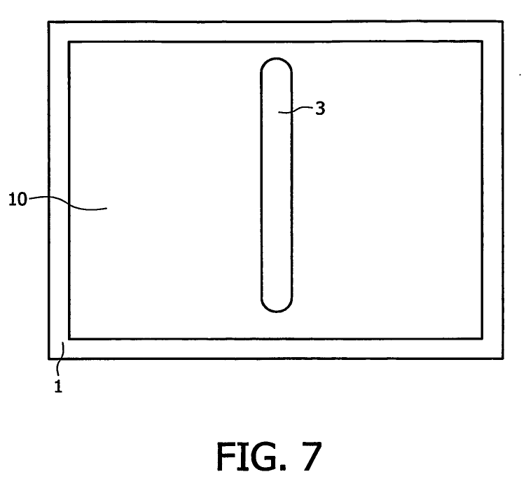

FIG. 7 is a plan view of a substrate with a sea of insulating material printed onto it to define a groove.

Referring to FIG. 1, an AMLCD panel is formed on an electrically insulating substrate 1 that may be optically transparent, on which an active switching matrix of LCD pixels P is provided, in a manner well known in itself in the art. Reference is directed to our EP-A-0 629 003. The substrate may also be semiconductve e.g. for a liquid crystal on silicon display, or conductive with an insulating layer beneath the TFTs and other conductive elements to prevent shorting. The pixels P_{x,y} are arranged in a rectangular x, y array and are operated by x and y driver circuits, via row and column address lines.

Considering the pixel P_{0,0} by way of example, it includes a liquid crystal display element L_{0,0} which is switched between different optical transmissivities by means of TFT_{0,0} that has its gate connected to driver line x₀ and its source coupled to driver line y₀. By applying suitable voltages to the lines x₀, y₀, transistor TFT_{0,0} can be switched on and off and thereby control the operation of the LCD element L_{0,0}. It will be understood that each of the pixels P of the display is of a similar construction and that the pixels can be scanned row by row on operation of the x and y driver circuits in a manner well known in itself.

Referring to FIGS. 2a to 2f, FIG. 2a illustrates a substrate 1, for example a glass substrate, prior to processing. FIG. 2b shows the substrate 1 overlaid with a photodefinable insulator material 2. FIG. 2c illustrates a groove 3 formed in the insulator material 2, with rounded edges 4 at the top of the groove 3. FIG. 2d illustrates the groove 3 filled with a conductive ink 5. FIG. 2e illustrates the conductive ink 5 after curing and FIG. 2f illustrates the resulting structure after the layer of photodefinable insulator material 2 has been reduced in thickness.

Referring to FIGS. 2 and 3, the photodefinable insulator material 2, is for example HD Microsystems™ PI-2730 series polyimide material, such as PI-2731 or HD Microsystems™ HD8000 series polyimide material. The steps required to process this and other similar photodefinable materials are well-known to the skilled person and will therefore only be described in outline in this specification. For further details, reference is directed to HD Microsystems™ PI-2730 Series Low Stress Photodefinable Polyimide Product Information and Process Guidelines.

The photodefinable insulator material 2 is deposited onto the substrate in any one of a number of possible ways, including spin coating, printing, spraying or blading (step s1). The material 2 is then partially cured using a bake process (step s2), which leaves the insulator material dry but soluble in developer solution. The required groove pattern is then produced by light exposure of all areas except the groove 3, using the Mercury broadband spectrum, or G-line (step s3). The PI-2730 series material is, for example, negative working so that exposed areas become insoluble. The resulting material is then developed, for example using HD Microsystems™ DE-9040 developer solution and rinsed with HD Microsystems™ RI-9140 rinse solution or N-Butylacetate (step s4). A final curing step is then carried out (step s5). The material tends to be left with a curved profile, as shown in FIG. 2c, which is advantageous in that subsequent layers can pass over the top of the groove and connect to any structure within the groove with a reduced probability of fracture at the smooth edge 4.

There are a number of alternative routes which would be well known to those skilled in the art for defining the groove, depending on the insulator material being used. For example, referring to FIG. 4, for either a photodefinable or non-photodefinable insulator material, the material 2 is deposited on the substrate 1 by any suitable technique (step s10), fully cured (step s11) and a metal layer, for example aluminum, is then sputtered onto the insulator to form a hard, in situ, mask (step s12). The metal layer is coated with a photoresist (step s13) and this is pre-baked (step s14). The required groove pattern is then exposed (step s15), developed (step s16) and the photoresist post-baked (step s17). The exposed metal in the groove is wet etched (step s18) to define the groove pattern in the insulator material 2 underneath. The photoresist may then be stripped off (step s19) and the organic insulator 2 underneath the metal layer is then dry etched (step s20) to define the groove 3. Altematively, rather than stripping the photoresist at step s19, this step may be omitted, in which case the etchants used in step s20 will remove the photoresist. Finally, the metal mask is stripped off to produce the structure shown in FIG. 2c (step s21).

In a further example shown in FIG. 5, the insulator material 2 is deposited (step s30), partly cured (step s31), coated with a photoresist (step s32) and the photoresist exposed (step s33) to define the groove pattern. The photoresist is then developed (step s34), and development is continued, a process which is also referred to as wet etching, to remove the organic layer 2 to form the groove 3 (step s35). The photoresist is then removed (step s36) and the insulator fully cured (step s37).

Referring to FIG. 6, once the groove 3 has been defined, it is filled with a desired metal precursor 5 or suspension of particles in a printing medium, or ink, using a doctor blade, by analogy to the way a printing cliché would be filled with ink (step s40). This leaves the groove 3 filled with the conductive ink 5, as shown, for example, in FIG. 2d.

The conductive ink is then cured (step s41) to obtain a highly conducting medium. After curing, a descum planar etching process may be performed to remove any excess material remaining outside the grooves (step s42).

During the curing process (step s41), the ink 5 shrinks towards the bottom of the groove 6, as shown in FIG. 2e, by an amount that depends on its composition and which may result, for example, in shrinkage to 25 per cent. of its original volume.

For high levels of shrinkage, further processing, for example, deposition of further layers over the substrate, may be difficult. In this case, the cured insulator material 2 is dry etched to reduce its thickness (step s43), as shown in FIG. 2f, although the reduction is arranged to maintain the curved top edge 4, which is advantageous for the reasons set out above. Organic insulators will etch in pure oxygen or an oxygen/sulphur hexafluoride (O₂/SF₆) mixture or oxygen/carbon tetrafluoride (O₂/CF₄) mixture. The thickness is reduced to the extent necessary to be compatible with subsequent processing.

From reading the present disclosure, other variations and modifications will be apparent to persons skilled in the art. Such variations and modifications may involve equivalent and other features which are already known in the field of producing conductive layers on substrates.

Referring to FIG. 7, as an alterative to defining a groove in an insulator in the production of a substrate for an active matrix LCD, a printing process such as offset lithography is used to print an insulating precursor 10 onto the substrate 1 so as to define a confinement groove 3, and the insulating precursor is then cured to produce the insulating material 10. The groove is again filled using a blading technique, as explained above with reference to FIG. 6.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A method of producing a conductive layer (5) on a substrate (1), comprising the steps of:
defining a groove (3) for the conductive layer (5) using a photodefinable insulator material (2); and
filling the groove (3) with a material capable of forming the conductive layer (5).

2. A method according to claim 1, wherein the step of defining the groove (3) comprises:
depositing the insulator material (2) onto the substrate (1);
defining a pattern in the insulator material; and
processing the pattern to form the groove (3).

3. A method according to claim 1, comprising filling the groove (3) using a blading technique.

4. A method according to claim 1, wherein the material capable of forming the conductive layer (5) comprises a metal precursor.

5. A method according to claim 1, wherein the material capable of forming the conductive layer (5) comprises a conductive ink.

6. A method according to claim 4, further comprising curing the material to obtain the conductive layer (5).

7. A method according to claim 6, further comprising etching the insulator material to reduce its thickness relative to the thickness of the conductive layer.

8. A method according to claim 6, comprising depositing one or more further functional layers over the conductive layer.

9. A method according to claim 1, wherein the conductive layer comprises a row or column line in an active matrix liquid crystal display.

10. An active matrix liquid crystal display including a conductive layer made by a method according to claim 1.

11. A device comprising a substrate (1) overlaid with a photodefinable insulator material (2), the material having a groove (3) for a conductive layer (5) defined therein.

12. A device according to claim 11, further comprising a conductive layer (5) in the groove (3).

13. A device according to claim 11, comprising an active matrix liquid crystal display.

14. A method of producing a conductive layer (5) on a substrate (1), comprising the steps of:
defining a groove (3) for the conductive layer (5); and
blading a material capable of forming the conductive layer (5) into the groove.

15. A method according to claim 14, comprising defining the groove (3) by printing an insulating material onto the substrate.

16. A method according to claim 14, wherein the step of defining the groove (3) includes depositing a material (2) onto the substrate (1) and defining the groove (3) in the material.

17. A method according to claim 16, wherein the material (2) comprises a photodefinable material.

18. A method according to claim 14, wherein the substrate comprises a substrate for use in an active matrix liquid crystal display.

19. A method of producing a conductive layer (5) on a substrate for an active matrix liquid crystal display, the method comprising the steps of printing an insulating material (10) onto the substrate (1) such that the printed material defines a groove (3) for the conductive layer and filling the groove with a material capable of forming the conductive layer (5).
